(19) United States
(12) Patent Application Publication
(10) Pub. No.: US 2016/0343552 A1
(43) Pub. Date: Nov. 24, 2016

(54) DEPOSITION OF SOLID STATE ELECTROLYTE ON ELECTRODE LAYERS IN ELECTROCHEMICAL DEVICES

(71) Applicant: APPLIED MATERIALS, INC., Santa Clara, CA (US)

(72) Inventors: Lizhong SUN, San Jose, CA (US); Byung-Sung Leo KWAK, Portland, OR (US); Joseph G. GORDON, II, San Jose, CA (US)

(21) Appl. No.: 15/112,419

(22) PCT Filed: Jan. 26, 2015
(86) PCT No.: PCT/US2015/012928

§ 371 Date: Jul. 18, 2016

Related U.S. Application Data
(60) Provisional application No. 62/043,920, filed on Aug. 29, 2014.
(60) Provisional application No. 61/931,299, filed on Jan. 24, 2014.

(51) Int. Cl. H01J 37/34; C23C 14/06; C23C 14/34; H01M 10/0525; H01M 10/0562

(52) U.S. Cl. CPC H01J 37/3426; H01M 10/0525; H01M 10/0562; H01J 37/3473; C23C 14/3457; C23C 14/0676; H01M 2300/0068

(57) ABSTRACT

Methods and apparatus are described for improving the fabrication of thin film electrochemical devices such as thin film batteries and electrochromic devices, with respect to deposition of LiPON, or other lithium ion conducting electrolyte, thin films on electrodes such as Li metal, Li—CoO₂, WO₃, NiO, etc. A method of fabricating an electrochemical device in a deposition system may comprise: configuring an electrically conductive layer substantially peripherally to a portion of the surface of an electrode layer of the electrochemical device; electrically connecting the electrically conductive layer to an electrically conductive, but electrically floating, surface; and depositing a lithium ion conducting solid state electrolyte layer on the portion of the surface of the electrode layer of the electrochemical device within the deposition chamber, wherein the depositing comprises forming a plasma within the deposition chamber; wherein during the depositing, the electrically conductive, but electrically floating, surface is within the deposition chamber.

### CROSS-REFERENCE TO RELATED APPLICATIONS

This application claims the benefit of U.S. Provisional Application No. 61/931,299 filed Jan. 24, 2014 and U.S. Provisional Application No. 62/043,920 filed Aug. 29, 2014.

### FIELD

Embodiments of the present disclosure relate to methods of depositing a solid state electrolyte on electrode layers in electrochemical devices, and deposition tool configurations for the same.

### BACKGROUND

In the fabrication of thin film electrochemical devices such as thin film batteries (TFB) and electrochromic devices there are problems associated with deposition of LiPON, or other lithium ion conducting solid state electrolyte, thin films on electrodes such as Li metal, LiCoO₂, WO₃, NiO, NiWO, etc. when using prior art deposition techniques. Prior art deposition techniques can lead to device failures, yield losses and/or throughput limitations—the throughput limitations being due to the need to either use complicated fabrication processes or deposit thick electrolyte layers to mitigate device failures and yield losses. Clearly, there is a need for improved deposition processes and improved fabrication apparatuses which can overcome these problems.

### SUMMARY

The present disclosure involves methods of directly depositing uniform layers of solid state electrolyte, such as lithium phosphorous oxynitride (LiPON), onto an electrode, such as lithium metal, LiCoO₂ or WO₃, of an electrochemical device. In the case of LiPON deposition on Li metal the present disclosure involves some methods with the advantageous effect that a passivation layer or other buffer layer may not be needed to stop the formation of an undesirable layer of lithium nitride—in some embodiments, direct deposition of LiPON on lithium metal becomes practical. In the case of LiPON deposition generally, the present disclosure involves some methods for forming a film with the advantageous effect that the film may be formed without defects such as islands of Li₂O; in some embodiments, methods of the present disclosure make the use of thinner layers of LiPON possible and also provide LiPON layers without discoloration, due to the absence of the Li₂O defects. It is speculated that the methods may involve effectively “diffusing” the electron concentration or any charged particles that accumulate on the deposition surfaces of the device substrate/stack during electrolyte deposition (due to the plasma in the deposition chamber) over a surface area larger than that of the deposition surfaces of the substrate/stack where the electrolyte is being deposited. The diffusing of electrons above the substrate/stack may be achieved by electrically connecting an electrically conductive layer positioned on top of or in close proximity to, the substrate to the electrically conductive, but electrically floating, surfaces in the deposition chamber. In some embodiments, this diffusing may be between surfaces of the electrochemical device stack/substrate and the process kit/pedestal inside a sputtering chamber. In some embodiments the electrically conductive layer could be any electrically conductive piece with openings for devices to be fabricated—e.g. an electrically conductive shadow mask. The electrically conductive surfaces in the deposition chamber can be a clamp ring in a deposition chamber, such as a physical vapor deposition (PVD) chamber for example, and for an inline tool it can be a carrier/holder on which the substrate(s) are mounted, for example.

According to some embodiments of the present disclosure, a method of fabricating an electrochemical device on a substrate in a deposition system may comprise: configuring an electrically conductive layer substantially peripherally to a portion of the surface of an electrode layer of the electrochemical device; electrically connecting the electrically conductive layer to an electrically conductive, but electrically floating, surface; and depositing a lithium ion conducting solid state electrolyte layer on the portion of the surface of the electrode layer of the electrochemical device within a deposition chamber, the deposition system comprising the deposition chamber, wherein the depositing comprises forming a plasma within the deposition chamber; wherein during the depositing, the electrically conductive layer and the electrically conductive, but electrically floating, surface are within the deposition chamber.

According to some embodiments of the present disclosure, an apparatus for fabricating an electrochemical device on a substrate may comprise: a deposition system for depositing a lithium ion conducting solid state electrolyte layer on a portion of the surface of an electrode layer of the electrochemical device, the system comprising: a deposition chamber; a deposition source for lithium ion conducting solid state electrolyte material; a substrate holder for the substrate; and an electrically conductive layer configured substantially peripherally to the portion of the surface of the electrode layer, the electrically conductive layer being electrically connected to an electrically conductive, but electrically floating, surface within the deposition chamber.

Furthermore, according to some embodiments of the present disclosure, an apparatus for fabricating an electrochemical device on a substrate may comprise: a deposition system for depositing a lithium ion conducting solid state electrolyte layer on a portion of the surface of an electrode layer of the electrochemical device, the system comprising: a deposition chamber; and a deposition source for lithium ion conducting solid state electrolyte material; a substrate carrier for moving the substrate through the deposition system; and an electrically conductive layer configured substantially peripherally to the portion of the surface of the electrode layer, the electrically conductive layer being electrically connected to an electrically conductive, but electrically floating, surface.

### BRIEF DESCRIPTION OF THE DRAWINGS

These and other aspects and features of the present disclosure will become apparent to those ordinarily skilled in the art upon review of the following description of specific embodiments in conjunction with the accompanying figures, wherein:

FIG. 1 is a cross-sectional representation of a prior art thin film battery;

FIG. 2 is a cross-sectional representation of a vertical stack electrochemical device;

FIG. 3 is a schematic representation of a deposition system for a cluster tool, according to some embodiments;

FIG. 4 is a schematic representation of a deposition system for an in-line tool, according to some embodiments;

FIG. 5 is a plot of voltage against capacity for a battery with a LiPON layer deposited using a conventional LiPON deposition process, where first charging curve 501 at 0.1 C and first discharge curve 502 at 0.1 C are shown;

FIG. 6 is a plot of voltage against capacity for a battery with a LiPON layer deposited using a LiPON deposition process according to some embodiments, where first charging curve 601 at 0.1 C and first discharge curve 602 at 0.1 C are shown;

FIG. 7 is a schematic illustration of a thin film deposition cluster tool, according to some embodiments;

FIG. 8 is a representation of a thin film deposition system with multiple in-line tools, according to some embodiments; and

FIG. 9 is a representation of an in-line deposition tool, according to some embodiments.

### DETAILED DESCRIPTION

Embodiments of the present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. In the present disclosure, an embodiment showing a singular component should not be considered limiting; rather, the disclosure is intended to encompass other embodiments including a plurality of the same component, and vice-versa, unless explicitly stated otherwise herein. Moreover, it is not intended for any term in the present disclosure to be ascribed an uncommon or special meaning unless explicitly set forth as such. Further, the present disclosure encompasses present and future known equivalents to the known components referred to herein by way of illustration.

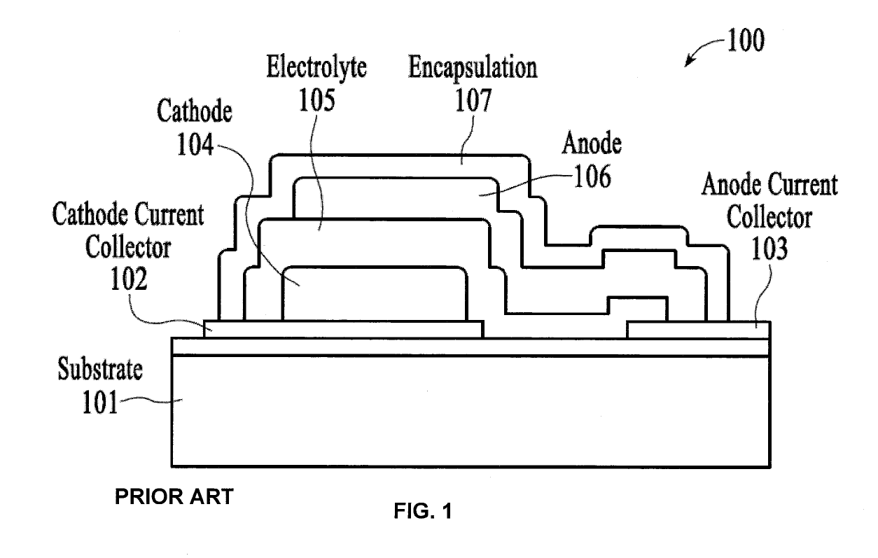

FIG. 1 shows a cross-sectional representation of a typical thin film battery (TFB). The TFB device structure 100 with anode current collector 103 and cathode current collector 102 are formed on a substrate 101, followed by cathode 104, solid state electrolyte 105 and anode 106; although the device may be fabricated with the cathode, electrolyte and anode in reverse order. Furthermore, the cathode current collector (CCC) and anode current collector (ACC) may be deposited separately. For example, the CCC may be deposited before the cathode and the ACC may be deposited after the electrolyte. The device may be covered by an encapsulation layer 107 to protect the environmentally sensitive layers from oxidizing agents. Note that the component layers are not drawn to scale in the TFB device shown in FIG. 1.

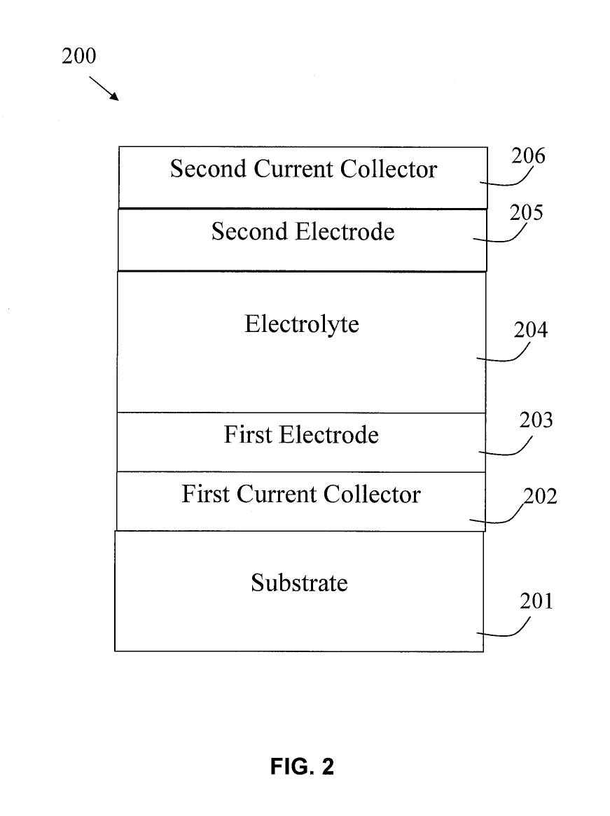

FIG. 2 shows an example of an electrochemical device with a vertical stack, fabricated according to certain embodiments; the methods of the present disclosure may also be used to fabricate devices with the general configuration of FIG. 1. In FIG. 2, the vertical stack 200 comprises: a substrate 201, a first current collector layer 202, a first electrode layer 203, a solid state electrolyte layer 204, a second electrode layer 205 and a second current collector 206. There may also be (not shown) a protective coating over the entire stack, and electrical contacts for the anode and cathode sides of the electrochemical device.

For a TFB the vertical stack of FIG. 2 may comprise: a substrate 201, an ACC 202, an anode layer 203, a solid state electrolyte layer 204, a cathode layer 205 and a CCC layer. Whereas, for an electrochromic device the vertical stack of FIG. 2 may comprise: a transparent substrate 201, a first transparent conductive oxide (TCO) layer 202, a first electrode layer 203, a solid state electrolyte layer 204, a second electrode layer 205 and a second TCO layer 206. The first and second electrode layers will typically be anode and cathode.

In a typical TFB device structure, such as shown in FIGS. 1 & 2, the electrolyte—a dielectric material such as lithium phosphorous oxynitride (LiPON)—is sandwiched between two electrodes—the anode and cathode. LiPON is a chemically stable (against Li metal) solid state electrolyte with a broad working voltage range (up to 5.5 V) and relatively high ionic conductivity (1-2 μS/cm). Solid state batteries, especially the thin film version, contain LiPON as an electrolyte as such cells are capable of more than 20,000 charge/discharge cycles with only 0.001% capacity loss/cycle. The conventional method used to deposit LiPON is physical vapor deposition (PVD) radio frequency (RF) sputtering of a Li₃PO₄ target in a N₂ ambient.

In solid state battery structures, where Li is involved as the anode material, the reactivity of the Li presents significant challenges in creating the battery. Such challenging situations arise when the Li anode needs to be protected in a conventional order of fabricating the battery, for example in a thin film (vacuum deposited) solid state battery, where on a substrate, cathode current collector, cathode, electrolyte and anode are formed sequentially in this approximate order, leaving the top Li anode to be coated in some way to protect it from reactions with ambient atmosphere. Another such situation arises when an “inverted” battery structure is considered—anode current collector first, followed by Li anode, electrolyte, and cathode. This structure can be either vacuum deposited or deposited by non-vacuum methods (slot die, printing, etc.). The inventors found that the challenge in the case of the inverted battery structure arises when the electrolyte layer, such as LiPON, needs to be deposited on the Li metal surface, and the conventional sputter deposition method in a nitrogen ambient may result in an undesirable layer of lithium nitride being formed at the interface between the Li metal and the LiPON. Or, worse yet, the N₂ plasma may consume all of the Li metal during the LiPON deposition leaving no charge carriers or reservoir of Li for the battery.

Furthermore, when LiPON is deposited on a cathode layer such as LiCoO₂, the inventors observed that conventional sputter deposition methods in a nitrogen/argon ambient may result in a dissociated deposition of the LiPON such that areas of lithium oxide may be formed within the LiPON layer, instead of a uniform LiPON film—these “LiPON” layers needing to be thicker than a single phase LiPON layer in order to mitigate arcing and shorting across the electrolyte during TFB operation.

In electrochromic devices, where an electrode such as a WO₃ layer is involved as a cathode material, which needs to be as transparent as possible in its clear state, the challenge arises when the electrolyte layer, such as LiPON, needs to be deposited on the WO₃ layer surface, and the conventional sputter deposition method in a nitrogen/argon ambient may result in a non-uniform and dissociated deposition of the LiPON such that areas of lithium oxide, instead of a uniform LiPON film, may be formed. A brown discoloration is observed in the areas of lithium oxide, which discoloration may be due to (1) unwanted lithiation of the WO₃ and/or (2) dissociated LiPON material. This discoloration not only affects the device performance (color modulation) during lithium insertion and de-insertion, but also has an impact on lifetime for an electrochromic device. Furthermore, undesirable pinholes in the LiPON layer, which may be associated with the dissociated LiPON, can result in shorting and/or arcing during electrochromic device operation.

Described herein in some embodiments are methods and apparatuses for improving the fabrication of thin film electrochemical devices such as thin film batteries (TFB) and electrochromic devices, with respect to deposition of LiPON, or other lithium ion conducting electrolyte, thin films on electrodes such as Li metal, LiCoO₂, WO₃, NiO, NiWO, etc.

Deposition of a LiPON layer on a lithium metal surface may be needed in various electrochemical devices, including a TFB. The conventional method used to deposit LiPON is physical vapor deposition (PVD) radio frequency (RF) sputtering of a Li₃PO₄ target in a nitrogen ambient. The problem is that the sputtering nitrogen plasma causes the following reaction: 6Li+N₂→2Li₃N, once the substrate (lithium metal) meets the nitrogen plasma before the LiPON can cover it up. The product, L₃N, has a very small voltage range (˜0.4 V) vs. Li reference electrode. While formation of Li₃N in itself is not an issue (Li₃N is a Li ion conductor), it is found by the present inventors that the reaction is not self-limiting but continues to eat up the lithium metal, the charge carrier for the battery, leaving only the charge carriers in the cathode for the battery operation. Here, we are assuming that the cathode is deposited in a lithiated, fully discharged state, from which the cycling carriers are drawn. Such cells without a reservoir of additional Li ion charge carriers typically show lower cyclability and capacity retention as the loss of charge carriers, Li, by various mechanisms over the life of the battery, directly affects the capacity and the cycle life. Therefore, a viable method of depositing LiPON onto lithium metal is key in fabricating high performance functional batteries, of the types described above.

The present disclosure describes some methods of directly depositing a solid state lithium ion conducting electrolyte, lithium phosphorous oxynitride (LiPON), onto lithium metal, without the need for a passivation layer or other buffer layer to stop the formation of an undesirable layer of lithium nitride. It is speculated that some methods of this disclosure may involve “diffusing” the electron concentration or substrate bias or any charged particles that accumulate on the deposition surfaces of the device substrate during LiPON plasma deposition over a surface area larger than that of the deposition surfaces of the substrate where LiPON is being deposited on lithium metal, which is discussed in more detail below. One consequence of the diffusing can be elimination of differential bias in the deposition zone against the surroundings. The diffusing of the electrons above the substrate may be achieved by electrically connecting an electrically conductive layer (such as an electrically conductive shadow mask) on top of the substrate to the electrically conductive, but electrically floating, surfaces within the deposition chamber, which removes the electrons before they can participate in undesirable side-reactions on the surface of the depositing layer of material. In some embodiments, this diffusing may be between surfaces of the device substrate and electrically floating parts of a process kit, such as a pedestal and a clamp ring, inside a sputtering chamber. In some embodiments the electrically conductive layer could be any electrically conductive piece (e.g. metal piece) with openings for devices to be fabricated—e.g. a shadow mask. The electrically conductive surfaces in the deposition chamber can be a clamp ring for example, and for an inline tool it can be the carrier/holder on which the substrate(s) are mounted, for example.

The connection of the electrically conductive layer and conductive surfaces in the deposition chamber acting as an electron sink appears to stop, or at least significantly limit, the formation of lithium nitride on the lithium metal surface at the beginning of the LiPON deposition. This initial behavior appears to enable maintenance of smooth surface morphology for a conformal coverage by the subsequent deposition of material, stopping further reaction with Li. In other words, though with continued deposition, the function of the electron sink gradually diminishes because of the deposition of the electrically insulating LiPON on both the conductive layer and the substrate, the deposited conformal LiPON layer on top of the lithium metal now acts as an increasingly effective separation layer—preventing direct contact of nitrogen plasma with the lithium metal.

Furthermore, it should be noted that the inventors tried a number of different methods for LiPON deposition on Li in order to find an approach that did not result in lithium nitride formation, and some of these methods did not work. For example, LiPON was deposited on Li where surface voltage, charges, etc. were modulated by modulating the overall impedance of the substrate area with an electrical connection of a blocking capacitor between the pedestal—on which the substrate is mounted, although there is no electrical connection between the pedestal and any electrically conductive part of the substrate—and the chamber body, which is grounded. For a PVD chamber, for example, this may be achieved by connecting the blocking capacitor to the pedestal upon which the substrate sits, which may be used to modulate the chamber impedance and the chamber/substrate bias, and for a chamber of an inline fabrication system this might be achieved by biasing the substrate carrier. These methods did not preventing lithium nitride formation, at least in the case of blocking capacitors of various capacitances (10 pF and 16 pF) being placed between the substrate pedestal and earth.

The forming of a stable stack on Li, such as the TFB version of the stack of FIG. 2, also provides opportunities to create cell stacks of hybrid nature, such as using very thick non-vacuum deposited cathode layers with liquid electrolyte that can lead to much higher capacity, energy density and lower cost. Lower cost can result from the non-vacuum method of forming the thick cathode. For example, a hybrid cell stack might be a “laminated dual-substrate structure” where one side is substrate/ACC/Li/LiPON and the other one is substrate/CCC/cathode/liquid electrolyte.

Deposition of a LiPON layer on an electrode, such as a LiCoO₂ layer or an electrode/coloration layer in an electrochromic device, may be needed in various electrochemical devices. The conventional method used to deposit LiPON is physical vapor deposition (PVD) radio frequency (RF) sputtering of a Li₃PO₄ target in a nitrogen/argon ambient. The problem is that the sputtering nitrogen/argon plasma can cause the LiPON film to be deposited as a non-uniform dissociated film including areas of lithium oxide or LiPON deficient in phosphorus and nitrogen. These dissociated LiPON layers need to be thicker than a single phase LiPON layer in order to mitigate arcing and shorting across the solid state electrolyte during TFB operation, said shorting being found by the inventors to be correlated with the areas of lithium oxide. Furthermore, the LiPON layers deposited by conventional methods on electrochromic electrodes such as WO₃ have areas of lithium oxide which areas have been found by the inventors to be correlated with discoloration and undesirable lithium insertion into the electrode. The lithium oxide formation is hypothesized to be due to a side reaction at the deposition surface which utilizes available electrons: Li⁺+e⁻→Li and 4Li+O₂→2Li₂O.

The present disclosure describes some methods of directly depositing a solid state lithium conducting electrolyte, lithium phosphorous oxynitride (LiPON), onto an electrode layer, without forming areas of lithium oxide within the LiPON layer, thus enabling use of thinner LiPON layers in devices, and avoiding discoloration in electrochromic devices. It is speculated that some methods of this disclosure may involve “diffusing” the electron concentration or substrate bias or any charged particles that accumulate on the deposition surfaces of the device substrate during LiPON plasma deposition over a surface area larger than that of the deposition surfaces of the substrate where LiPON is being deposited on an electrode such as a LiCoO₂ cathode layer or an electrochromic electrode/coloration layer, which is discussed in more detail below. One consequence of the diffusing can be elimination of differential bias in the deposition zone against the surroundings. The diffusing of the electrons above the substrate may be achieved by electrically connecting an electrically conductive layer (such as an electrically conductive shadow mask) on top of the substrate to the electrically conductive, but electrically floating, surfaces within the deposition chamber, which removes the electrons before they can participate in undesirable side-reactions on the surface of the depositing layer of material. In some embodiments, this diffusing may be between surfaces of the electrochemical device stack/substrate and the process kit/pedestal inside a sputtering chamber. In some embodiments, the electrically conductive layer could be any metal piece with openings for devices to be fabricated—e.g. an electrically conductive shadow mask. The electrically conductive surfaces in the deposition chamber can be a clamp ring, for example, and for an inline tool it can be the carrier on which the substrate(s) are mounted, for example.

According to some embodiments of the present disclosure, a method of fabricating an electrochemical device on a substrate in a deposition system may comprise: configuring an electrically conductive layer substantially peripherally to a portion of the surface of an electrode layer of the electrochemical device; electrically connecting the electrically conductive layer to an electrically conductive, but electrically floating, surface; and depositing a lithium ion conducting solid state electrolyte layer on the portion of the surface of the electrode layer of the electrochemical device within a deposition chamber, the deposition system comprising the deposition chamber, wherein the depositing comprises forming a plasma within the deposition chamber; wherein during the depositing, the electrically conductive layer and the electrically conductive, but electrically floating, surface are within the deposition chamber. Furthermore, the electrochemical device may be a thin film battery, an electrochromic device, or other electrochemical device. In some embodiments, the lithium ion conducting solid state electrolyte layer may be a LiPON layer and the electrode layer may be a lithium metal layer. Furthermore, in some embodiments the lithium ion conducting solid state electrolyte layer may be a LiPON layer and the electrode layer may be a LiCoO₂ layer. Yet furthermore, the lithium ion conducting solid state electrolyte may be a LiPON layer and the electrode layer may be a WO₃ layer. In some embodiments, the portion of the surface of the electrode layer may be the entire surface of the electrode layer.

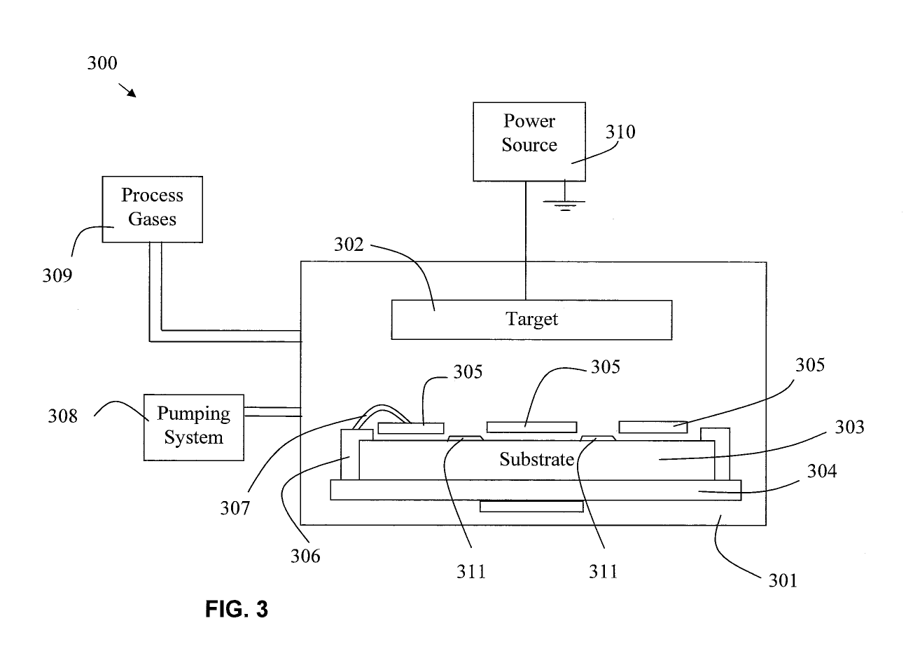

FIG. 3 shows a schematic cross-sectional representation of an example of a deposition tool configured for deposition methods according to embodiments of the present disclosure. The sputter deposition tool 300 includes a vacuum chamber 301, a sputter target 302, a substrate 303 and a substrate holder/pedestal 304. For LiPON deposition the target 302 may be Li₃PO₄ and a suitable substrate 303 may be, depending on the type of electrochemical device, silicon, silicon nitride on Si, glass, PET (polyethylene terephthalate), mica, metal foils such as copper, etc., with current collector(s) and electrode layer(s) already deposited and patterned, if necessary. (See FIG. 1 for an example of patterned current collectors and electrodes.) A shadow mask 305 is positioned above the deposition surface of the substrate, and is attached by an electrically conductive strip 307 to the clamp ring 306. The chamber 301 has a vacuum pump system 308 and a process gas delivery system 309. Power source 310 is shown connected to the target; this power source may include matching networks and filters for handling RF, and in embodiments may include multiple frequency sources if needed. The “diffusing” of the plasma environment in the deposition tool during deposition is achieved by electrically connecting an electrically conductive layer, such as shadow mask 305, on top of the substrate to the electrically conductive, but electrically floating, surfaces in the deposition chamber, such as the clamp ring 306, by using an electrically conductive strip 307, for example, a Cu tape. Furthermore, in embodiments the shadow mask may be directly electrically connected to the substrate holder/pedestal 304. Areas 311 of solid state lithium ion conducting electrolyte material are shown deposited on portions of the surface of the substrate 303 using the methods according to the present disclosure.

The electrically conductive, but electrically floating, layer could be any electrically conductive piece (e.g. metal piece) with openings for devices to be fabricated—e.g. a shadow mask. The electrically conductive surfaces in the deposition chamber can be clamp rings, pedestal, etc., for example, and for an inline tool it can be the carrier or sub-carrier on which the substrate(s) are mounted, for example. Furthermore, in embodiments the surface area of the aforementioned clamp rings, pedestals, carriers, sub-carriers, etc. may be increased by roughening their surfaces.

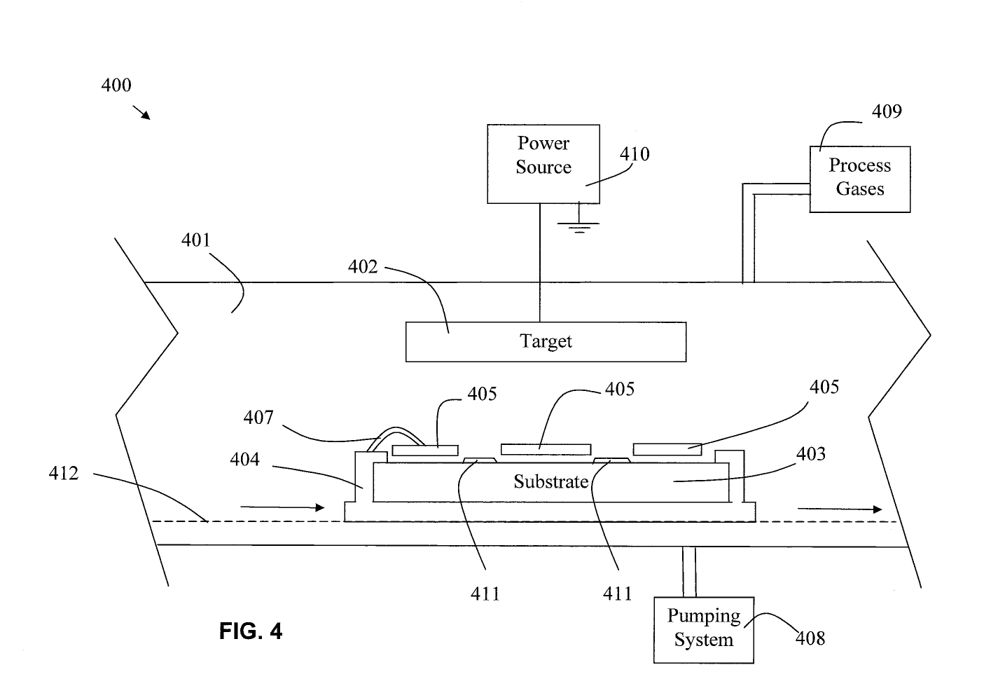

FIG. 4 shows a schematic cross-sectional representation of an example of a deposition tool configured for deposition methods according to embodiments of the present disclosure. The sputter deposition tool 400 includes a vacuum chamber 401, a sputter target 402, a substrate 403, a substrate carrier 404 and a substrate conveyor 412 for moving the substrate on the substrate carrier through the tool. For LiPON deposition the target 402 may be Li₃PO₄ and a suitable substrate 403 may be, depending on the type of electrochemical device, silicon, silicon nitride on Si, glass, PET (polyethylene terephthalate), mica, metal foils such as copper, etc., with current collector(s) and electrode layer(s) already deposited and patterned, if necessary. (See FIG. 1 for an example of patterned current collectors and electrodes.) A shadow mask 405 is positioned above the deposition surface of the substrate, and is attached by an electrically conductive strip 407 to the substrate carrier 404. The chamber 401 has a vacuum pump system 408 and a process gas delivery system 409. Power source 410 is shown connected to the target; this power source may include matching networks and filters for handling RF, and in embodiments may include multiple frequency sources if needed. The “diffusing” of the plasma environment in the deposition tool during deposition is achieved by electrically connecting an electrically conductive layer, such as shadow mask 405, on top of the substrate to an electrically conductive, but electrically floating, surface, such as the substrate carrier 404, by using an electrically conductive strip 407, for example, a Cu tape. Areas 411 of solid state lithium ion conducting electrolyte material are shown deposited on portions of the surface of the substrate 403 using the methods according to the present disclosure.

Experiments were conducted to test the efficacy of some embodiments of the present disclosure. LiPON was sputter deposited in a nitrogen ambient on to lithium metal on an electrically insulating glass substrate where a shadow mask with an electrically conductive top surface was held above the lithium-coated glass substrate and where an interlayer—between Li and LiPON—is not used. (The shadow mask is made of Invar and is 200 microns thick, although it is expected that shadow masks made of other materials such as Inconel will also work, and it is also expected that the thickness of the shadow mask may also be varied, for example a shadow mask can have a thickness of less than 200 microns or a thickness up to 1 millimeter and still work.) The openings in the LiPON shadow mask are larger than the Li area. The mask was electrically connected to the electrically conductive clamp ring inside a PVD deposition chamber by copper metal tape. The lack of any darkening in the appearance of the deposited stack compared with the appearance of the stack prior to electrolyte deposition indicates that there is no significant Li₃N formation at the interface between Li and LiPON. A similar result was achieved when the substrate was changed to copper metal in an otherwise identical configuration. In contrast, LiPON sputter deposition in a nitrogen ambient on to lithium metal on copper foil where the electrically conductive shadow mask is not electrically connected to the electrically conductive, but electrically floating, clamp ring, or any other electrically conductive surfaces in the deposition chamber exhibits the characteristic darkening associated with formation of Li₃N at the interface between Li and LiPON.

Furthermore, LiPON was sputter deposited in a nitrogen ambient on to a WO₃ electrode on a substrate using an electrically conductive shadow mask electrically connected to the wafer clamp ring using Cu tape—the lack of any non-uniform discoloration in the appearance of the deposited stack indicates that a LiPON layer of uniform composition has been deposited. In contrast, when LiPON was deposited on a WO₃ electrode layer on ITO on glass using a conventional manufacturing process (where there is no electrically conductive shadow mask electrically connected to electrically conductive, but electrically floating, surfaces in the deposition chamber) there is a discoloration in the appearance of the deposited stack which is characteristic of the formation of regions of lithium oxide instead of LiPON. (The central area of the substrate appeared to be primarily a lithium oxide and the peripheral area of the substrate appeared to be closer to a LiPON composition.)

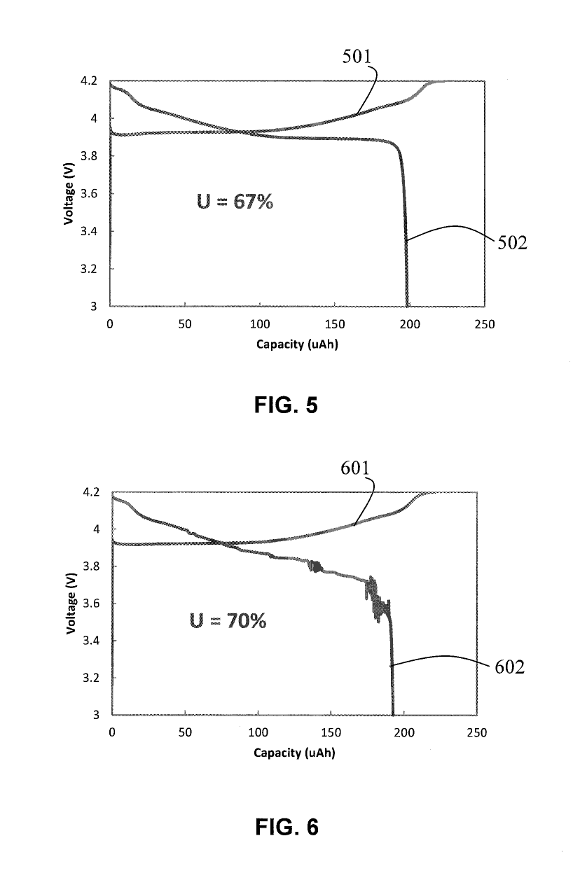

Furthermore, to demonstrate that thinner layers of LiPON may be successfully used in TFB devices when deposition methods of the present disclosure are used, device stacks were fabricated with 4 microns of LiCoO₂ on which was deposited 0.45 microns of LiPON using methods according to the present disclosure (an electrically conductive shadow mask was electrically connected to the electrically floating clamp ring in a sputter deposition chamber) followed by deposition of 5 microns of lithium metal. These TFB cells (some 30 devices) were tested and a 100 percent yield of cells with voltages ranging from 1.2 V to 2.5 V, indicating the good insulating properties of the LiPON layer, were recorded. The capacity utilization (U) of a device with the 0.45 micron thick LiPON electrolyte deposited according to embodiments of the present disclosure was found to be comparable to that of a conventionally fabricated device with a 3 micron thick LiPON electrolyte—see FIGS. 5 & 6 with U of 67% and 70%, respectively—this provides further confirmation of the viability of the methods of the present disclosure. Furthermore, experiments with thinner layers of LiPON show that layers as thin as 0.3 microns have good insulating properties between TFB electrodes, and these 0.3 micron thick layers also have the advantage of providing an ionic resistance between electrodes which is ten times less than for a 3 micron thick LiPON electrolyte layer. (The ionic resistance scales linearly with the layer thickness.)

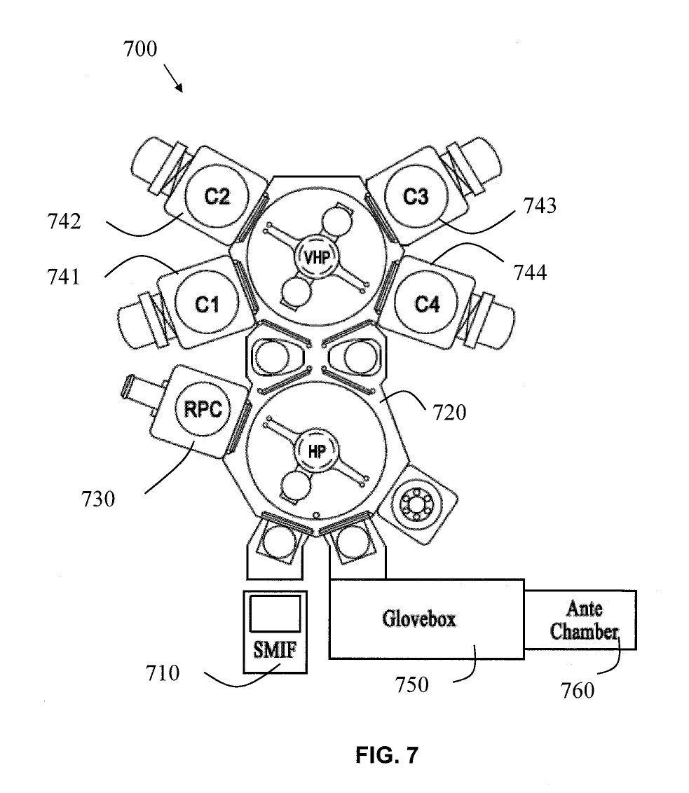

FIG. 7 is a schematic illustration of a processing system 700 for fabricating an electrochemical device, such as a TFB or an electrochromic device, according to some embodiments of the present disclosure. The processing system 700 includes a standard mechanical interface (SMIF) 710 to a cluster tool 720 equipped with a reactive plasma clean (RPC) chamber 730 and process chambers C1-C4 (741, 742, 743 and 744), which may be utilized in the process described above. A glovebox 750 may also be attached to the cluster tool if needed. The glovebox can store substrates in an inert environment (for example, under a noble gas such as He, Ne or Ar), which is useful after alkali metal/alkaline earth metal deposition. An ante chamber 760 to the glovebox may also be used if needed—the ante chamber is a gas exchange chamber (inert gas to air and vice versa) which allows substrates to be transferred in and out of the glovebox without contaminating the inert environment in the glovebox. (Note that a glovebox can be replaced with a dry room ambient of sufficiently low dew point, as used by lithium foil manufacturers.) The chambers C1-C4 can be configured for part or all of the process for manufacturing electrochemical devices which may include, for example, deposition of a Li metal layer on a substrate, deposition of a LiPON electrolyte layer (by RF sputtering a Li₃PO₄ target in nitrogen gas ambient) using an electrically conductive shadow mask electrically connected to an electrically floating surface of the deposition chamber, as described above. It is to be understood that while a cluster arrangement has been shown for the processing system 700, a linear system may be utilized in which the processing chambers are arranged in a line without a transfer chamber so that the substrate continuously moves from one chamber to the next chamber.

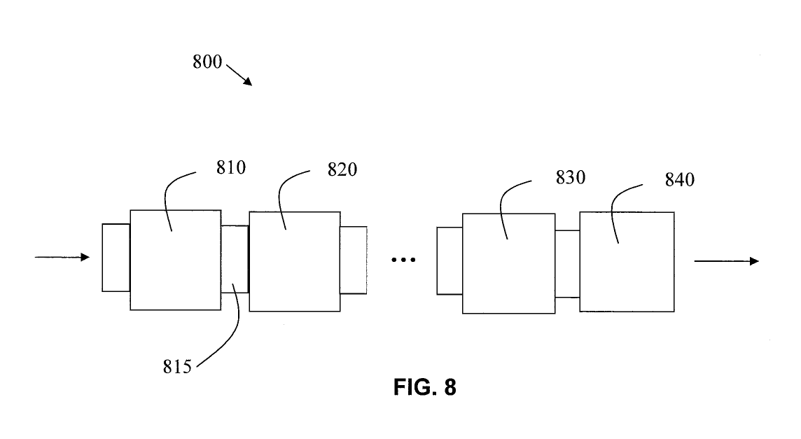

FIG. 8 shows a representation of an in-line fabrication system 800 with multiple in-line tools 810, 820, 830, 840, etc., according to some embodiments of the present disclosure. In-line tools may include tools for depositing all the layers of an electrochemical device—including both TFBs and electrochromic devices. Furthermore, the in-line tools may include pre- and post-conditioning chambers. For example, tool 810 may be a pump down chamber for establishing a vacuum prior to the substrate moving through a vacuum airlock 815 into a deposition tool 820. Some or all of the in-line tools may be vacuum tools separated by vacuum airlocks 815. Note that the order of process tools and specific process tools in the process line will be determined by the particular electrochemical device fabrication method being used. For example, one or more of the in-line tools may be dedicated to depositing a LiPON dielectric layer on a Li metal surface using an electrically conductive shadow mask electrically connected to an electrically floating surface of the deposition chamber, according to some embodiments of the present disclosure, as described above. Furthermore, substrates may be moved through the in-line fabrication system oriented either horizontally or vertically. Yet furthermore, the in-line system may be adapted for reel-to-reel processing of a web substrate.

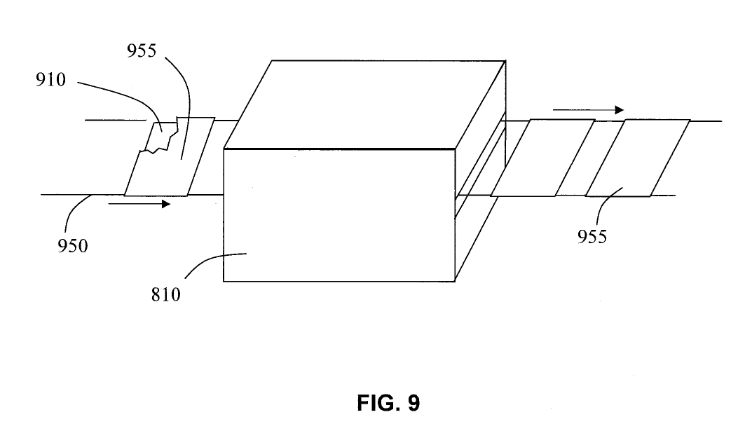

In order to illustrate the movement of a substrate through an in-line fabrication system such as shown in FIG. 8, in FIG. 9 a substrate conveyor 950 is shown with only one in-line tool 810 in place. A substrate carrier 955 containing a substrate 910 (the substrate carrier is shown partially cut-away so that the substrate can be seen) is mounted on the conveyor 950, or equivalent device, for moving the carrier and substrate through the in-line tool 810, as indicated. In some embodiments in-line platforms may be configured for vertical substrate orientation and in other embodiments in-line platforms may be configured for horizontal substrate orientation. Furthermore, an in-line process can be implemented on a reel-to-reel or web system.

An apparatus for fabricating an electrochemical device comprising a lithium metal electrode according to embodiments of the present disclosure may comprise: a system for depositing a layer of LiPON dielectric material on the lithium metal electrode on a substrate, the depositing being sputtering a Li₃PO₄ target in a nitrogen-containing ambient, where the ambient may also comprise argon, an electrically conductive layer being attached/in close proximity to the substrate, the electrically conductive layer being electrically connected to an electrically conductive, but electrically floating, surface of the chamber. The apparatus may be a cluster tool or an in-line tool.

An apparatus for fabricating an electrochemical device comprising a WO₃ electrode according to embodiments of the present disclosure may comprise: a system for depositing a layer of LiPON dielectric material on the WO₃ electrode on a substrate, the depositing being sputtering a Li₃PO₄ target in a nitrogen-containing ambient, where the ambient may also comprise argon, an electrically conductive layer being attached/in close proximity to the substrate, the electrically conductive layer being electrically connected to an electrically conductive, but electrically floating, surface of the chamber. The apparatus may be a cluster tool or an in-line tool.

An apparatus for fabricating an electrochemical device comprising a LiCoO₂ electrode according to embodiments of the present disclosure may comprise: a system for depositing a layer of LiPON dielectric material on the LiCoO₂ electrode on a substrate, the depositing being sputtering a Li₃PO₄ target in a nitrogen-containing ambient, where the ambient may also comprise argon, an electrically conductive layer being attached/in close proximity to the substrate, the electrically conductive layer being electrically connected to an electrically conductive, but electrically floating, surface of the chamber. The apparatus may be a cluster tool or an in-line tool.

More generally, an apparatus for fabricating an electrochemical device comprising an electrode according to embodiments of the present disclosure may comprise: a system for depositing a layer of solid state electrolyte material on the electrode on a substrate, wherein an electrically conductive layer is attached/in close proximity to the substrate, the electrically conductive layer being electrically connected to an electrically conductive, but electrically floating, surface within the deposition chamber. The apparatus may be a cluster tool or an in-line tool.

More specifically, according to some embodiments of the present disclosure, an apparatus for fabricating an electrochemical device on a substrate may comprise: a deposition system for depositing a lithium ion conducting solid state electrolyte layer on a portion of the surface of an electrode layer of the electrochemical device, the system comprising: a deposition chamber; a deposition source for lithium ion conducting solid state electrolyte material; a substrate holder for the substrate; and an electrically conductive layer configured substantially peripherally to the portion of the surface of the electrode layer, the electrically conductive layer being electrically connected to an electrically conductive, but electrically floating, surface within the deposition chamber. The electrically conductive layer may be a shadow mask, for example, and the electrically conductive, but electrically floating, surface may be a substrate clamp ring and/or a substrate holder/pedestal, for example.

Furthermore, according to some embodiments of the present disclosure, an apparatus for fabricating an electrochemical device on a substrate may comprise: a deposition system for depositing a lithium ion conducting solid state electrolyte layer on a portion of the surface of an electrode layer of the electrochemical device, the system comprising: a deposition chamber; and a deposition source for lithium ion conducting solid state electrolyte material; a substrate carrier for moving the substrate through the deposition system; and an electrically conductive layer configured substantially peripherally to the portion of the surface of the electrode layer, the electrically conductive layer being electrically connected to an electrically conductive, but electrically floating, surface. The electrically conductive layer may be a shadow mask, for example, and the electrically conductive, but electrically floating, surface may be a substrate carrier, for example.

In general, it is expected that the present disclosure can be used in the fabrication of any electrochemical devices that have a solid state electrolyte deposition on an electrode surface—for example, energy storage devices, electrochromic devices, TFBs, electrochemical sensors, etc.

Although specific examples of TFBs with Li anodes, LiPON solid state electrolytes, etc. have been described herein, it is expected that the present disclosure may be applied to a wider range of TFBs comprising different materials. Examples of materials for the different component layers of a TFB may include one or more of the following. The substrate may be silicon, silicon nitride on Si, glass, PET (polyethylene terephthalate), mica, metal foils such as copper, etc. The ACC and CCC may be one or more of Ag, Al, Au, Ca, Cu, Co, Sn, Pd, Zn and Pt which may be alloyed and/or present in multiple layers of different materials and/or include Ti adhesion layers, etc. The cathode may be LiCoO₂, V₂O₅, LiMnO₂, Li₅FeO₄, NMC (NiMnCo oxide), NCA (NiCoAl oxide), LMO (LiₓMnO₂), LFP (LiₓFePO₄), LiMn spinel, etc. The solid state electrolyte may be a lithium ion conducting electrolyte material including materials such as LiPON, LiI/Al₂O₃ mixtures, LLZO (LiLaZr oxide), LiSiCON, etc. The anode may be Li, Si, silicon-lithium alloys, lithium silicon sulfide, Al, Sn, etc.

Although specific examples of electrochromic devices with WO₃ cathodes, LiPON solid state electrolytes, etc. have been described herein, it is expected that the present disclosure may be applied to a wider range of electrochromic devices comprising different materials. Examples of materials for the different component layers of an electrochromic device may include one or more of the following. The transparent substrate may be glass (such as soda lime glass, borosilicate glass, etc.), plastics (such as polyimide, polyethylene terephalate, polyethylene naphthalate, etc.), etc. The TCO may be indium tin oxide (ITO), aluminum-doped zinc oxide, zinc oxide, CNT and/or graphene containing transparent materials, etc. The cathode may be a coloration layer such as WO₃, WO, where x is less than 3, CrOₓ, MoOₓ, etc. The solid state electrolyte may be LiPON, TaOₓ, LiₓM_{y}O_{z} where M is one or more metals and/or semiconductors, etc. The anode may be nickel oxide, NiO₂, NiOₓ where x is less than 2, IrOₓ and VOₓ, etc. and additives such as Mg, Al, Si, Zr, Nb, Ta, W, etc. may be beneficial.

Although FIGS. 3 & 8 show chamber configurations with horizontal planar target and substrate, the target and substrate may be held in vertical planes—the latter configuration can assist in mitigating particle problems if the target itself generates particles. Furthermore, the position of the target and substrate may be switched, so that the substrate is held above the target. Yet furthermore, the substrate may be flexible and moved in front of the target by a reel to reel system, the target may be a rotating cylindrical target, the target may be non-planar, and/or the substrate may be non-planar.

In yet further embodiments, a bias may be applied to the substrate clamp ring in addition to using the electron sink method described herein—the bias on the clamp ring provides another adjustment to potentially improve the effectiveness of the electron sink method and thus potentially allow the use of higher deposition rates for device layers without compromising the composition and crystallinity of the deposited layers.

Furthermore, specific deposition techniques have been described herein for the lithium ion conducting solid state electrolyte materials but deposition techniques for these layers according to methods of the present disclosure may be: DC, AC, RF, and UHF sputtering, sputtering with combinations of different frequency sources, remote plasma based sputtering, deposition with inductively-coupled and capacitively-coupled plasma sources, deposition with ECR sources, and deposition including combinations of the above, etc. Furthermore, there are other ion/electron sources, e.g., ion beams and electron beams, that can be used to create a plasma environment in the deposition zone above the substrate.

Herein it is disclosed that the electrically conductive layer may be held in close proximity to the electrode layer of the electrochemical device, or even touching. Example configurations may include: wherein at least a portion of the surface of the electrically conductive layer is less than about 200 microns from the surface of the electrode layer of the electrochemical device; wherein at least a portion of the surface of the electrically conductive layer is less than about 2 millimeters from the surface of the electrode layer of the electrochemical device; and wherein at least a portion of the surface of the electrically conductive layer is less than about 2 centimeters from the surface of the electrode layer of the electrochemical device.

Although embodiments of the present disclosure have been particularly described with reference to certain embodiments thereof, it should be readily apparent to those of ordinary skill in the art that changes and modifications in the form and details may be made without departing from the spirit and scope of the disclosure.

1. A method of fabricating an electrochemical device in a deposition system, comprising:
configuring an electrically conductive layer substantially peripherally to a portion of the surface of an electrode layer of said electrochemical device;
electrically connecting said electrically conductive layer to an electrically conductive, but electrically floating, surface; and
depositing a lithium ion conducting solid state electrolyte layer on said portion of the surface of said electrode layer of said electrochemical device within a deposition chamber, said deposition system comprising said deposition chamber, wherein said depositing comprises forming a plasma within said deposition chamber;
wherein during said depositing, said electrically conductive layer and said electrically conductive, but electrically floating, surface are within said deposition chamber.

2. The method of claim 1, wherein said electrochemical device is a thin film battery.

3. The method of claim 1, wherein said electrochemical device is an electrochromic device.

4. The method of claim 1, wherein said lithium ion conducting solid state electrolyte layer is a LiPON layer and said electrode layer is a lithium metal layer.

5. The method of claim 1, wherein said lithium ion conducting solid state electrolyte layer is a LiPON layer and said electrode layer is a LiCoO₂ layer.

6. The method of claim 1, wherein said lithium ion conducting solid state electrolyte layer is a LiPON layer and said electrode layer is a WO₃ layer.

7. The method of claim 1, wherein at least a portion of said electrically conductive layer is at less than about 2 centimeters from said electrode layer of said electrochemical device.

8. The method of claim 1, wherein said electrically conductive layer is a shadow mask.

9. The method of claim 1, wherein said electrically conductive, but electrically floating, surface is a substrate clamp ring of a substrate holder for said substrate.

10. The method of claim 1, wherein said electrically conductive, but electrically floating, surface is a substrate carrier for said substrate,

11. An apparatus for fabricating an electrochemical device on a substrate comprising:
a deposition system for depositing a lithium ion conducting solid state electrolyte layer on a portion of the surface of an electrode layer of said electrochemical device, said system comprising:
a deposition chamber;
a deposition source for lithium ion conducting solid state electrolyte material;
a substrate holder for said substrate; and
an electrically conductive layer configured substantially peripherally to said portion of the surface of said electrode layer, said electrically conductive layer being electrically connected to an electrically conductive, but electrically floating, surface within said deposition chamber.

12. The apparatus of claim 11, wherein said substrate holder comprises a clamp ring, and wherein said electrically conductive, but electrically floating, surface within said deposition chamber is said clamp ring.

13. An apparatus for fabricating an electrochemical device on a substrate comprising:
a deposition system for depositing a lithium ion conducting solid state electrolyte layer on a portion of the surface of an electrode layer of said electrochemical device, said system comprising:
a deposition chamber; and
a deposition source for lithium ion conducting solid state electrolyte material;
a substrate carrier for moving said substrate through said deposition system; and
an electrically conductive layer configured substantially peripherally to said portion of the surface of said electrode layer, said electrically conductive layer being electrically connected to an electrically conductive, but electrically floating, surface.

14. The apparatus of claim 13, wherein said electrically conductive layer is an electrically conductive shadow mask.

15. The apparatus of claim 13, wherein said electrically conductive, but electrically floating, surface within said deposition chamber is said substrate carrier.

16. The apparatus of claim 11, wherein said electrically conductive layer is an electrically conductive shadow mask.
